(19) United States
(12) Patent Application Publication
(10) Pub. No.: US 2022/0122974 A1
(43) Pub. Date: Apr. 21, 2022

(54) MEMORY CELL AND SEMICONDUCTOR DEVICE WITH THE SAME

(71) Applicant: SK hynix Inc., Gyeonggi-do (KR)

(72) Inventors: Seung Wook RYU, Gyeonggi-do (KR); Ki Hong LEE, Gyeonggi-do (KR)

(21) Appl. No.: 17/193,291

(22) Filed: Mar. 5, 2021

(30) Foreign Application Priority Data
Oct. 15, 2020 (KR) 10-2020-0133521

(51) Int. Cl. H01L 27/108

(52) U.S. Cl. CPC H01L 27/10805; H01L 27/10897

(57) ABSTRACT

A semiconductor device includes: a memory cell array including a plurality of memory cells that are vertically stacked over a body substrate, wherein each of the memory cells includes: a bit line vertically oriented with respect to the body substrate; a capacitor laterally spaced apart from the bit line; an active layer laterally oriented between the bit line and the capacitor; a word line positioned on any one of an upper surface and a lower surface of the active layer, and laterally extending in a direction intersecting with the active layer; and a bit line discharge portion coupled to the bit line.

### CROSS-REFERENCE TO RELATED APPLICATIONS

The present application claims priority to Korean Patent Application No. 10-2020-0133521, filed on Oct. 15, 2020, which is incorporated herein by reference in its entirety.

### BACKGROUND

### 1. Field

Various embodiments of the present invention relate to a semiconductor device, and more particularly, to a memory cell and a semiconductor device including the memory cell.

### 2. Description of the Related Art

Recently, the size of memory cells has been reduced continuously in order to increase the net die of a memory device. As the size of memory cells becomes finer, parasitic capacitance has to be reduced and the capacitance has to be increased, but it is difficult to increase the net die due to structural limitations of the memory cells.

### SUMMARY

Embodiments of the present invention are directed to highly integrated memory cells, and a semiconductor device including the highly integrated memory cells.

In accordance with an embodiment of the present invention, a semiconductor device includes: a memory cell array including a plurality of memory cells that are vertically stacked over a body substrate, wherein each of the memory cells includes: a bit line vertically oriented with respect to the body substrate; a capacitor laterally spaced apart from the bit line; an active layer laterally oriented between the bit line and the capacitor; a word line positioned on any one of an upper surface and a lower surface of the active layer, and laterally extending in a direction intersecting the active layer; and a bit line discharge portion coupled to the bit line.

In accordance with another embodiment of the present invention, a semiconductor device includes: a body substrate; a memory cell array including a bit line that is vertically oriented with respect to the body substrate; a peripheral circuit portion positioned at a higher level than the memory cell array; a bit line discharge portion positioned at a lower level than the memory cell array and coupled to the bit line; and a bonding pad coupling the bit line of the memory cell array and the peripheral circuit portion to each other, wherein the bit line discharge portion is spaced apart from the body substrate.

In accordance with yet another embodiment of the present invention, a semiconductor device includes: a body substrate; a memory cell array including a bit line that is vertically oriented with respect to the body substrate; a peripheral circuit portion positioned at a higher level than the memory cell array; a bit line discharge portion positioned at a lower level than the memory cell array and coupled to the bit line; and a bonding pad coupling the bit line of the memory cell array and the peripheral circuit portion to each other, wherein the bit line discharge portion contacts the body substrate.

### BRIEF DESCRIPTION OF THE DRAWINGS

FIG. 1 is a cross-sectional diagram illustrating a semiconductor device in accordance with an embodiment of the present invention.

FIG. 2 is a cross-sectional diagram illustrating a semiconductor device in accordance with another embodiment of the present invention.

FIG. 3 is a cross-sectional diagram illustrating a semiconductor device in accordance with another embodiment of the present invention.

FIGS. 4A and 4B are cross-sectional diagrams illustrating semiconductor devices 400 and 401 in accordance with other embodiments of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. Hereinafter, the various embodiments of the present invention will be described in detail with reference to the attached drawings.

In the following embodiment of the present invention, memory cells may be vertically stacked to increase memory cell density and reduce parasitic capacitance.

In realizing a 3-dimensional (3D) Dynamic Random Access Memory (DRAM) cell array, the memory cell density may be improved through a peripheral circuit-under-cell (PUC) structure where a peripheral circuit portion is placed at a lower level than a memory cell array.

According to the following embodiments of the present invention, a discharging path is formed through a bit line to minimize the effect of a floating body of a transistor. Accordingly, the characteristics of a transistor may be maximized.

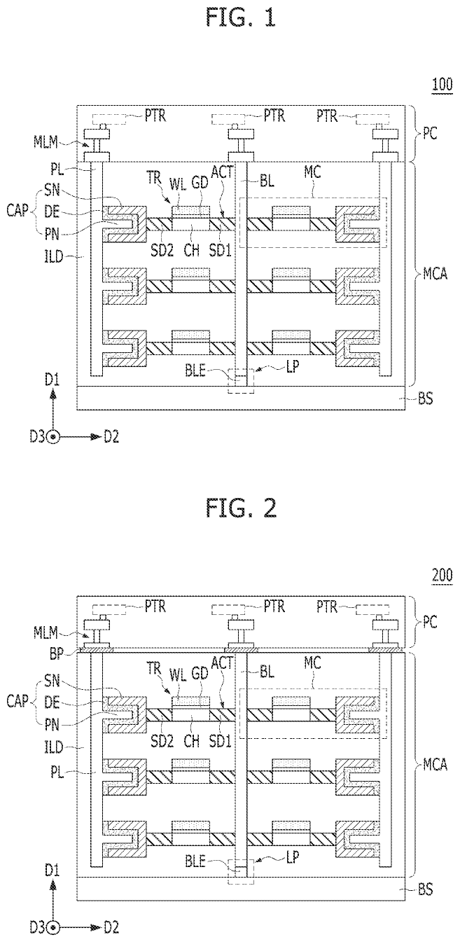

FIG. 1 is a cross-sectional diagram illustrating a semiconductor device in accordance with an embodiment of the present invention.

Referring to FIG. 1, the semiconductor device 100 may include a body substrate BS, and a memory cell array MCA may be formed in the upper portion of the body substrate BS. The memory cell array MCA may be oriented perpendicular to the body substrate BS. The body substrate BS may include a plane, and the memory cell array MCA may be oriented perpendicular to the plane of the body substrate BS. The memory cell array MCA may be vertically oriented upwardly from the body substrate BS in a first direction D1. The memory cell array MCA may include a three-dimensional array of memory cells MC. The memory cell array MCA may include a plurality of memory cells MC. For example, the memory cells MC of the memory cell array MCA may be vertically oriented in the first direction D1. In this disclosure, a vertical direction may include a literal vertical direction and the first direction D1.

Each of the memory cells MC of the memory cell array MCA may include a bit line BL, a transistor TR, a capacitor CAP, and a plate line PL. The transistor TR and the capacitor CAP may be laterally oriented in a second direction D2. Each of the memory cells MC may further include a word line WL, and the word line WL may be elongated in a third direction D3. In the individual memory cell MC, the bit line BL, the transistor TR, the capacitor CAP, and the plate line PL may be laterally arranged along the second direction D2. The memory cell array MCA may include a DRAM memory cell array. According to another embodiment of the present invention, the memory cell array MCA may include a PCRAM, a RERAM, a MRAM, and the like, and the capacitor CAP may be replaced with another memory element.

The body substrate BS may be a material appropriate for semiconductor processing. The body substrate BS may include at least one of a conductive material, a dielectric material, and a semiconductor material. Various materials may be formed in the upper portion of the body substrate BS. The body substrate BS may include a semiconductor substrate. The body substrate BS may be formed of a silicon-containing material. The body substrate BS may include silicon, monocrystalline silicon, polysilicon, amorphous silicon, silicon germanium, monocrystalline silicon germanium, polycrystalline silicon germanium, carbon-doped silicon, a combination thereof, or a mufti-layer thereof. The body substrate BS may include other semiconductor materials, such as germanium. The body substrate BS may include a group-III/V semiconductor substrate, for example, a compound semiconductor substrate, such as GaAs. The body substrate BS may include a Silicon-On-Insulator (SOI) substrate.

The semiconductor device 100 may further include a peripheral circuit portion PC. The peripheral circuit portion PC may be positioned at a higher level than the memory cell array MCA. The peripheral circuit portion PC may include a plurality of control circuits PTR, and the control circuits PTR may control the memory cell array MCA. The peripheral circuit portion PC may further include a multi-level metal line MLM coupled to the control circuits PTR. The control circuits PTR of the peripheral circuit portion PC may include an N-channel transistor, a P-channel transistor, a CMOS circuit, or a combination thereof. The control circuits PTR of the peripheral circuit portion PC may include an address decoder circuit, a read circuit, and a write circuit. The control circuits PTR of the peripheral circuit portion PC may include a planar channel transistor, a recess channel transistor, a buried gate transistor, and a fin channel transistor (FinFET), etc.

The control circuits PTR of the peripheral circuit portion PC may include a sense amplifier, a word line driver, and the like. The sense amplifier may be electrically connected to the bit line BL, and the word line driver may be electrically connected to the word line WL. The peripheral circuit portion PC may further include a multi-level metal line MLM, and the multi-level metal line MLM may be positioned between the control circuits PTR and the memory cell array MCA.

The memory cell array MCA may include a stack of at least two or more memory cells MC. At least two or more memory cells MC may be vertically stacked in the upper portion of the body substrate BS along the first direction D1.

The bit line BL may extend along the first direction D1 from the body substrate BS. The plane of the body substrate BS may extend along the second direction D2, and the first direction D1 may be perpendicular to the second direction D2. The bit line BL may be vertically oriented from the body substrate BS. The bit line BL may vertically extend upwardly from the body substrate BS. The control circuits PTR for controlling the operation of the bit line BL may be positioned at a higher level than the bit line BL.

The bottom portion of the bit line BL may be coupled to the body substrate BS. The bit line BL may have a pillar shape. The bit line BL may be referred to as a vertically oriented bit line or a pillar-type bit line. The memory cells MC that are vertically stacked along the first direction D1 may share one bit line BL. The bit line BL may include a conductive material. The bit line BL may include a silicon-based material, a metal-based material, or a combination thereof. The bit line BL may include polysilicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a stack (TiN/W) of titanium nitride and tungsten. The bit line BL may further include an ohmic contact layer, such as a metal silicide.

The transistors TR may be arranged laterally in the second direction D2. That is, the transistor TR may be positioned laterally between the bit line BL and the capacitor CAP. The transistor TR may be positioned at a higher level than the body substrate BS, and the transistor TR and the body substrate BS may be spaced apart from each other. The transistor TR may be referred to as a cell transistor. The second direction D2 may be parallel to the surface of the body substrate BS.

The transistor TR may include an active layer ACT, a gate dielectric layer GD, and a word line WL. The word line WL may extend along the third direction D3, and the active layer ACT may extend along the second direction D2. The third direction D3 may be perpendicular to the first direction D1. The active layer ACT may be laterally arranged from the bit line BL. The active layer ACT may be oriented parallel to the plane of the body substrate BS in the second direction D2.

The word line WL may have a single word line structure and may be positioned on one channel surface of the active layer ACT. A gate dielectric layer GD may be formed on the surface of the upper portion of the active layer ACT. A gate dielectric layer GD may be formed between the word line WL and the surface of the upper portion of the active layer ACT. The word line WL may be spaced apart from the active layer ACT by the gate dielectric layer GD.

The gate dielectric layer GD may include silicon oxide, silicon nitride, a metal oxide, a metal oxynitride, a metal silicate, a high-k material, a ferroelectric material, an anti-ferroelectric material or a combination thereof. The gate dielectric layer GD may include SiO₂, Si₃N₄, HfO₂, Al₂O₃, ZrO₂, AlON, HfON, HfSiO, HfSiON, and the like.

The word line WL may include a metal, a metal mixture, a metal alloy, or a semiconductor material. The word line WL may include titanium nitride, tungsten, polysilicon, or a combination thereof. For example, the word line WL may include a TiN/W stack in which titanium nitride and tungsten are sequentially stacked. The word line WL may include an N-type work function material or a P-type work function material. The N-type work function material may have a low work function of approximately 4.5 or less, and the P-type work function material may have a high work function of approximately 4.5 or more.

The active layer ACT may include a semiconductor material, an oxide semiconductor material, or a combination thereof. The active layer ACT may include doped polysilicon, undoped polysilicon, monocrystalline silicon, amorphous silicon, silicon germanium, indium gallium zinc oxide (IGZO), MoS2 or WS2. The active layer ACT may include a plurality of impurity regions. The impurity regions may include a first source/drain region SD1 and a second source/drain region SD2. The first source/drain region SD1 and the second source/drain region SD2 may be doped with an N-type impurity or a P-type impurity. The first source/drain region SD1 and the second source/drain region SD2 may be doped with an impurity of the same conductivity type. The first source/drain region SD1 and the second source/drain region SD2 may be doped with an N-type impurity. The first source/drain region SD1 and the second source/drain region SD2 may be doped with a P-type impurity. The first source/drain region SD1 and the second source/drain region SD2 may include at least one impurity selected among arsenic (As), phosphorus (P), boron (B), indium (In), and combinations thereof. The bit line BL may be electrically connected to a first edge portion of the active layer ACT, and the capacitor CAP may be electrically connected to a second edge portion of the active layer ACT. The first edge portion of the active layer ACT may be provided by the first source/drain regions SD1, and the second edge portion of the active layer ACT may be provided by the second source/drain regions SD2. The active layer ACT may further include a channel CH, and the channel CH may be defined between the first source/drain region SD1 and the second source/drain region SD2.

The active layer ACT neighboring in the third direction D3 may be supported by an inter-layer dielectric layer ILD. The inter-layer dielectric layer ILD may be formed between the memory cells MC that are vertically adjacent to each other in the first direction D1. The inter-layer dielectric layer ILD may include a dielectric material, such as silicon oxide.

The capacitor CAP may be positioned laterally from the transistor TR. The capacitor CAP may laterally extend from the active layer ACT along the second direction D2. The capacitor CAP may include a storage node SN, a dielectric layer DE, and a plate node PN. The storage node SN, the dielectric layer DE, and the plate node PN may be laterally arranged along the second direction D2. The storage node SN may have a laterally oriented cylinder-shape, and the plate node PN may have a shape extending into an inner wall and an outer wall of the cylindrical storage node SN. The dielectric layer DE may be positioned inside the storage node SN while surrounding the plate node PN. The plate node PN may be coupled to the plate line PL. The storage node SN may be electrically connected to the second source/drain region SD2. A portion of the second source/drain region SD2 may extend into the inside of the storage node SN.

The capacitor CAP may include a Metal-Insulator-Metal (MIM) capacitor. The storage node SN and the plate node PN may include a metal-based material. The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9, and the dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). According to another embodiment of the present invention, the dielectric layer DE may be formed of a composite layer including two or more layers of the high-k materials mentioned above,

The dielectric layer DE may be formed of zirconium-based oxide. The dielectric layer DE may have a stack structure including zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide-based layer (ZrO₂-based layer). According to another embodiment of the present invention, the dielectric layer DE may be formed of hafnium-based oxide. The dielectric layer DE may have a stack structure including hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as hafnium oxide-based layer (HfO₂-based layer). In the ZA stack, ZAZ stack, HA stack, and HAH stack, aluminum oxide (Al₂O₃) may have a larger band gap than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap than that of the high-k material. The dielectric layer DE may include silicon oxide (SiO₂) as a high band gap material other than aluminum oxide (Al₂O₃). Since the dielectric layer DE contains a high band gap material, leakage current may be suppressed. The high band gap material may be extremely thin. The high band gap material may be thinner than the high-k material. According to another embodiment of the present invention, the dielectric layer DE may include a laminated structure in which a high-k material and a high band gap material are alternately stacked. For example, ZAZA (ZrO₂/Al₂O₃/ZrO₂/Al₂O₃), ZAZAZ (ZrO₂/Al₂O₃/ZrO₂/Al₂O₃/ZrO₂), HAHA (HfO₂/Al₂O₃/HfO₂/Al₂O₃) or HAHAH (HfO₂/Al₂O₃/HfO₂/Al₂O₃/HfO₂). In the laminate structure as above, aluminum oxide (Al₂O₃) may be extremely thin.

According to another embodiment of the present invention, the dielectric layer DE may include a stack structure including zirconium oxide, hafnium oxide, and aluminum oxide, a laminate structure, or a mutual mixing structure.

According to another embodiment of the present invention, an interface control layer (not shown) for improving leakage current may be further formed between the storage node SN and the dielectric layer DE. The interface control layer may include titanium oxide (TiO₂). The interface control layer may also be formed between the plate node PN and the dielectric layer DE.

The storage node SN and the plate node PN may include a metal, a noble metal, a metal nitride, a conductive metal oxide, a conductive noble metal oxide, a metal carbide, a metal silicide, or a combination thereof. For example, the storage node SN and the plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), titanium a nitride/tungsten (TiN/W) stack, or a tungsten nitride/tungsten (WN/W) stack. The plate node PN may include a combination of a metal-based material and a silicon-based material. For example, the plate node PN may be a stack of titanium nitride/silicon germanium/tungsten nitride (TiN/Site/WN). In the titanium nitride/silicon germanium/tungsten nitride (TiN/SiGe/WN) stack, silicon germanium may be a gap-fill material filling the cylindrical inside of the storage node SN, and titanium nitride (TiN) may serve as a plate node of a substantial capacitor CAP. Tungsten nitride may be a low-resistance material. The bottom portion of the plate line PL may be insulated or float from the body substrate BS. The upper portion of the plate line PL may be coupled to the peripheral circuit portion PC.

The storage node SN may have a three-dimensional (3D) structure, and the storage node SN having the 3D structure may have a lateral 3D structure oriented along the second direction D2. As an example of the 3D structure, the storage node SN may have a cylinder shape, a pillar shape, or a pylinder shape. Herein, the pylinder shape may refer to a structure in which a pillar shape and a cylinder shape are merged.

Referring back to FIG. 1, the bottom portion of the bit line BL may be directly coupled to the body substrate BS by a bit line discharge portion BLE. In FIG. 1, the direct coupling is indicated by the reference numeral ‘LP’. Since the bit line BL is coupled to the body substrate BS, it may be referred to as a body-tied bit line. The bit line discharge portion BLE and the bit line BL may have the same width and may be positioned perpendicular to each other.

According to another embodiment of the present invention, the bit line discharge portion BLE may be a portion of the bit line BL, and the bit line discharge portion BLE may extend downwardly along the first direction D1 to be electrically connected to the body substrate BS.

The bit line discharge portion BLE may be formed of the same material as the bit line BL. According to another embodiment of the present invention, the bit line discharge portion BLE may be a material different from that of the bit line BL. The bit line discharge portion BLE may include a conductive material or a semiconductor material.

As described above, since the bottom portion of the bit line BL is coupled to the body substrate BS, it is possible to adjust the potential during the operation of the peripheral circuit portion PC. As a result, loss of charges stored in the inside of the capacitor CAP may be improved.

FIG. 2 is a cross-sectional diagram illustrating a semiconductor device in accordance with another embodiment of the present invention. In FIG. 2, the same reference numerals as in FIG. 1 denote the same constituent elements. Hereinafter, detailed descriptions of the same constituent elements will be omitted.

Referring to FIG. 2, the semiconductor device 200 may include a body substrate BS, and a memory cell array MCA may be formed in an upper portion of the body substrate BS. The memory cell array MCA may be oriented perpendicular to the body substrate BS. The memory cell array MCA may be vertically oriented upwardly from the body substrate BS in the first direction D1. The memory cell array MCA may include a three-dimensional array of memory cells MC. The memory cell array MCA may include a plurality of memory cells MC. For example, the memory cells MC of the memory cell array MCA may be vertically oriented along the first direction D1.

Each of the memory cells MC of the memory cell array MCA may include a bit line BL, a transistor TR, a capacitor CAP, and a plate line PL. The transistor TR and the capacitor CAP may be laterally oriented along the second direction D2. Each of the memory cells MC may further include a word line WL, and the word line WL may be elongated in the third direction D3. In each memory cell MC, the bit line BL, the transistor TR, the capacitor CAP, and the plate line PL may be laterally arranged along the second direction D2. The memory cell array MCA may include a DRAM memory cell array. According to another embodiment of the present invention, the memory cell array MCA may include a Phase Change Random Access Memory (PCRAM), a Resistive Random Access Memory (RERAM), a Magnetic Random Access Memory (MRAM), and the like, and the capacitor CAP may be replaced with another memory element.

The semiconductor device 200 may further include a peripheral circuit portion PC. The peripheral circuit portion PC may be positioned at a higher level than the memory cell array MCA. The peripheral circuit portion PC may include a plurality of control circuits PTR, and the control circuits PTR may control the memory cell array MCA. The peripheral circuit portion PC may further include a multi-level metal line MLM which is coupled to the control circuits PTR.

The bit line BL may be vertically oriented with respect to the body substrate BS. The bit line BL may vertically extend upwardly from the body substrate BS. The bottom portion of the bit line BL may be coupled to the body substrate BS.

The transistor TR may be positioned at a higher level than the body substrate BS. The transistor TR and the body substrate BS may be spaced apart from each other. The transistor TR may include an active layer ACT, a gate dielectric layer GD, and a word line WL. The word line WL may extend along the third direction D3, and the active layer ACT may extend along the second direction D2. The third direction D3 may be a direction perpendicular to the first direction D1. The active layer ACT may be laterally arranged from the bit line BL. The active layer ACT may be oriented parallel to a plane of the body substrate BS in the second direction D2.

The word line WL may have a single word line structure and may be positioned on one channel surface of the active layer ACT. A gate dielectric layer GD may be formed on the upper surface of the active layer ACT. The gate dielectric layer GD may be formed between the word line WL and the upper surface of the active layer ACT. The word line WL may be spaced apart from the active layer ACT by the gate dielectric layer GD. The active layer ACT may include a plurality of impurity regions. The impurity regions may include a first source/drain region SD1 and a second source/drain region SD2. The active layer ACT may further include a channel CH, and the channel CH may be defined between the first source/drain region SD1 and the second source/drain region SD2.

The active layer ACT neighboring in the third direction D3 may be supported by an inter-layer dielectric layer ILD. The inter-layer dielectric layer ILD may be formed between the memory cells MC neighboring vertically along the first direction D1. The inter-layer (dielectric layer ILD may include a dielectric material, such as silicon oxide.

The capacitor CAP may be laterally positioned from the transistor TR. The capacitor CAP may laterally extend from the active layer ACT along the second direction D2. The capacitor CAP may include a storage node SN, a dielectric layer DE, and a plate node PN. The storage node SN, the (dielectric layer DE, and the plate node PN may be laterally arranged along the second direction D2. The storage node SN may have a laterally oriented cylinder shape, and the plate node PN may have a shape extending into an inner wall and an outer wall of the cylindrical storage node SN. The dielectric layer DE may be positioned inside the storage node SN while surrounding the plate node PN. The plate node PN may be coupled to the plate line PL. The storage node SN may be electrically connected to the second source/drain region SD2. A portion of the second source/drain region SD2 may extend into the inside of the storage node SN.

Referring back to FIG. 2, the bottom portion of the bit line BL may directly land on the body substrate BS by the bit line discharge portion BLE. In FIG. 2, the direct landing is indicated by the reference numeral ‘LP’. The bit line discharge portion BLE may be formed of the same material as that of the bit line BL. The bit line discharge portion BLE may be a portion of the bit line BL and the bit line discharge portion BLE may extend downwardly in the first direction D1 to be electrically connected to the body substrate BS. The bit line discharge portion BLE may be formed of a material that is different from that of the bit line BL. The bit line discharge portion BLE may include a conductive material or a semiconductor material.

As described above, since the bottom portion of the bit line BL is coupled to the body substrate BS, it is possible to adjust the potential during the operation of the peripheral circuit portion PC. As a result, loss of charges stored in the capacitor CAP may be improved.

The memory cell array MCA and the peripheral circuit portion PC may be coupled to each other through wafer bonding. For example, the memory cell array MCA and the peripheral circuit portion PC may be coupled to each other through a bonding pad BP. The bonding pad BP may include a metal-based material. The peripheral circuit portion PC and the bit line BL may be coupled to each other through the bonding pad BP.

As described above, since the memory cell array MCA and the peripheral circuit portion PC are coupled to each other through the wafer bonding, the process for forming the memory cell array MCA and the process for forming the peripheral circuit portion PC may be performed independently. Accordingly, it is possible to improve deterioration in the characteristics of the transistor caused by interference between the memory cell array MCA and the peripheral circuit portion PC.

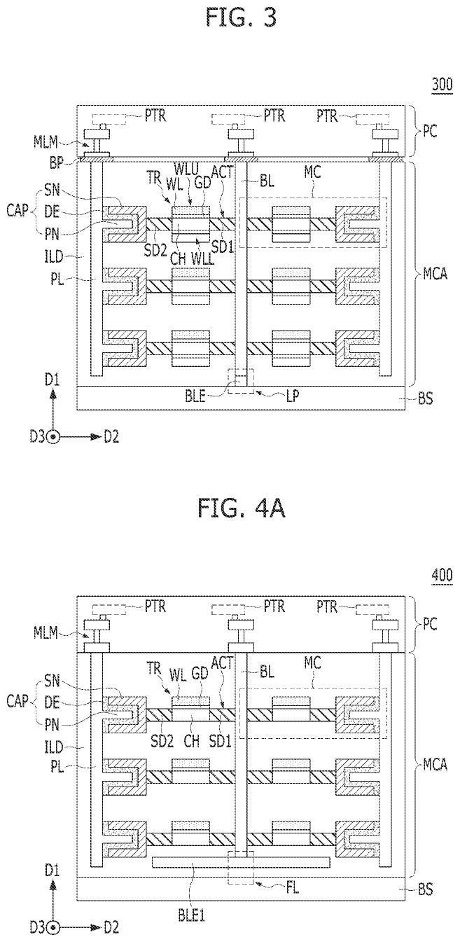

FIG. 3 is a cross-sectional diagram illustrating a semiconductor device 300 in accordance with another embodiment of the present invention. In FIG. 3, the same reference numerals as in FIGS. 1 and 2 denote the same constituent elements. Hereinafter, detailed descriptions on the same constituent elements will be omitted.

Referring to FIG. 3, the semiconductor device 300 may include a body substrate BS, a memory cell array MCA which is vertically oriented from the body substrate BS, and a peripheral circuit portion PC which is positioned at a higher level than the memory cell array MCA. Word lines WL of each memory cell MC may have a double word line structure and the active layer ACT is interposed between the word lines WL within each memory cell MC. A gate dielectric layer GD may be formed on the upper and lower surfaces of the active layer ACT. The word lines WL may include an upper word line WLU and a lower word line WLL within each memory cell MC. The upper word line WLU may be positioned on the upper surface of the active layer ACT, and the lower word line WLL may be positioned below the lower surface of the active layer ACT. A gate dielectric layer GD may be formed between the upper word line WLU and the upper surface of the active layer ACT, and the gate dielectric layer GD may also be formed between the lower word line WLL and the lower surface of the active layer ACT. The upper word line WLU and the lower word line WLL may be spaced apart from the active layer ACT by the gate dielectric layer GD.

The upper word line WLU and the lower word line WLL may have different potentials. For example, in each of the memory cells MC, a word line driving voltage may be applied to the upper word line WLU and a ground voltage may be applied to the lower word line WLL. The lower word line WLL may serve to block interference of the upper word lines WLU between the memory cells MC that are positioned vertically along the first direction D1. According to another embodiment of the present invention, the ground voltage may be applied to the upper word line WLU and the word line driving voltage may be applied to the lower word line WLL. According to another embodiment of the present invention, the upper word line WLU and the lower word line WLL may be coupled to each other.

According to another embodiment of the present invention, the word line WL may have a gate all around (GAA) structure where the word line WL surrounds the active layer ACT within each memory cell MC. The gate dielectric layer GD may be formed on the surfaces of the active layer ACT and the word line WL may surround the gate dielectric layer GD.

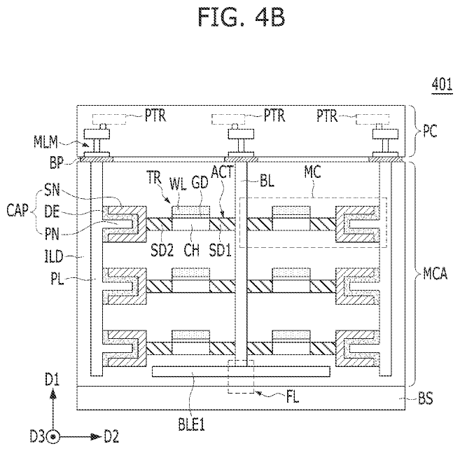

FIGS. 4A and 4B are cross-sectional diagrams illustrating semiconductor devices 400 and 401 in accordance with other embodiments of the present invention. In FIGS. 4A and 4B, the same reference numerals as in FIGS. 1 and 2 denote the same constituent elements. Hereinafter, detailed descriptions on the same constituent elements will be omitted. The semiconductor device 400 of FIG. 4A may have a structure in which a memory cell array MCA and a peripheral circuit portion PC are coupled to each other through a multi-level metal line MLM. The semiconductor device 401 of FIG. 4B may have a structure in which a memory cell array MCA and a peripheral circuit PC are coupled to each other through a bonding pad BP.

Referring to FIGS. 4A and 4B, the semiconductor devices 400 and 401 may include a body substrate BS, a memory cell array MCA that is vertically oriented from the body substrate BS, and a peripheral circuit portion PC that is positioned at a higher level than the memory cell array MCA. Each of the memory cells MC may have a single word line structure in which the word lines WL are positioned over an upper portion of the active layer ACT.

The bit line BL may be spaced apart from the body substrate BS. The bottom portion of the bit line BL may be coupled to the bit line discharge portion BLE1. The bit line discharge portion BLE1 may be spaced apart from the body substrate BS. In FIG. 4A, the bottom portion of the bit line BL coupled to the bit line discharge portion BLE1 spaced apart from the body substrate BS is indicated by the reference symbol ‘FL’. The bit line discharge portion BLE1 may float from the body substrate BS. The bit line discharge portion BLE1 may include a conductive material or a semiconductor material. The bit line discharge portion BLE1 may be parallel to the surface of the body substrate BS. The bit line discharge portion BLE1 may extend laterally along the second direction D2. The bit line discharge portion BLE1 may vertically overlap with the active layer ACT. The bit line discharge portion BLE1 may have a larger width than the bit line BL.

In the above-described embodiments of the present invention, the bit line discharge portions BLE and BLE1 may be referred to as a bit line discharge layer. By forming the bit line discharge portions BLE and BLE1, leakage current and refresh time of the transistor may be improved.

In a comparative example where the bit line discharge portions BLE and BLE1 are not provided, it is difficult to apply the body-tide structure to the memory cell array MCA and the body substrate BS. When a neighboring transistor is operated with respect to a reference transistor, a potential barrier of the reference transistor may be lowered due to the state of the body of the floated transistor, thereby causing loss of charges stored in the capacitor.

In another comparative example where the peripheral circuit portion PC is positioned below the memory cell array MCA, the memory cell array MCA may be formed after the peripheral circuit portion PC is formed. In this example, the thermal budget for the cell array process may affect the peripheral circuit portion PC, resulting in deterioration of the control circuits PTR of the peripheral circuit portion PC.

As described in the above-described embodiments, when the bit line BL contacts the body substrate BS, the potential of the bit line BL may be fixed, thereby minimizing the channel leakage of the transistor.

Also, as the peripheral circuit portion PC and the memory cell array MCA are independently formed, individual characteristics of the memory cell array MCA and the peripheral circuit portion PC may be maximized. In addition, since the independent formation of the peripheral circuit portion PC and the memory cell array MCA prevents the thermal interference between the memory cell array MCA and the peripheral circuit portion PC, characteristics may be maximized independently without deterioration of the peripheral circuit portion PC or deterioration of the transistor TR.

According to the embodiment of the present invention, since the bottom portion of a bit line is coupled to a substrate, the potential may be adjusted during the operation of a peripheral circuit portion. Consequently, loss of charges stored in a capacitor may be improved.

According to the embodiment of the present invention, the leakage current and refresh time of a transistor may be improved by forming a bit line discharge portion.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a memory cell array including a plurality of memory cells that are vertically stacked over a body substrate,
wherein each of the memory cells includes:
a bit line vertically oriented with respect to the body substrate;
a capacitor laterally spaced apart from the bit line;
an active layer laterally oriented between the bit line and the capacitor;
a word line positioned on any one of an upper surface and a lower surface of the active layer, and laterally extending in a direction intersecting the active layer; and
a bit line discharge portion coupled to the bit line.

2. The semiconductor device of claim 1, wherein the bit line discharge portion is positioned between the bit line and the body substrate.

3. The semiconductor device of claim 1, wherein the bit line discharge portion includes a conductive material or a semiconductor material.

4. The semiconductor device of claim 1, wherein the bit line discharge portion directly contacts the body substrate.

5. The semiconductor device of claim 1, wherein the bit line discharge portion is spaced apart from the body substrate.

6. The semiconductor device of claim 1, further comprising at least one control circuit which is positioned at a higher level than the memory cell array and controls the memory cell array.

7. The semiconductor device of claim 1, wherein the memory cell array is a portion of a Dynamic Random Access Memory (DRAM) cell array.

8. The semiconductor device of claim 1, wherein the active layer includes monocrystalline silicon, polysilicon, amorphous silicon, silicon germanium, indium gallium zinc oxide (IGZO), MoS2 or WS2.

9. A semiconductor device, comprising:
a body substrate;
a memory cell array including a bit line that is vertically oriented with respect to the body substrate;
a peripheral circuit portion positioned at a higher level than the memory cell array;
a bit line discharge portion positioned at a lower level than the memory cell array and coupled to the bit line; and
a bonding pad coupling the bit line of the memory cell array and the peripheral circuit portion to each other,
wherein the bit line discharge portion is spaced apart from the body substrate.

10. The semiconductor device of claim 9, wherein the bit line discharge portion is positioned between the bit line and the body substrate.

11. The semiconductor device of claim 9, wherein the bit line discharge portion includes a conductive material or a semiconductor material.

12. The semiconductor device of claim 9, wherein the peripheral circuit portion includes at least one control circuit which is positioned at a higher level than the memory cell array and controls the memory cell array.

13. The semiconductor device of claim 9, wherein the memory cell array is a portion of a DRAM cell array,

14. The semiconductor device of claim 9,
wherein the memory cell array includes a plurality of memory cells that are vertically stacked over the body substrate, and
wherein each of the memory cells includes:
a capacitor laterally spaced apart from the bit line;
an active layer laterally oriented between the bit line and the capacitor; and
a word line positioned in an upper portion of at least one of an upper surface and a lower surface of the active layer, and laterally extending in a direction intersecting the active layer.

15. A semiconductor device, comprising:
a body substrate;
a memory cell array including a bit line that is vertically oriented with respect to the body substrate;
a peripheral circuit portion positioned at a higher level than the memory cell array;
a bit line discharge portion positioned at a lower level than the memory cell array and coupled to the bit line; and
a bonding pad coupling the bit line of the memory cell array and the peripheral circuit portion to each other,
wherein the bit line discharge portion contacts the body substrate.

16. The semiconductor device of claim 15, wherein the bit line discharge portion is positioned between the bit line and the body substrate.

17. The semiconductor device of claim 15, wherein the peripheral circuit portion includes at least one control circuit which is positioned at a higher level than the memory cell array and controls the memory cell array.

18. The semiconductor device of claim 15, wherein the memory cell array is a portion of a DRAM cell array.

19. The semiconductor device of claim 15,
wherein the memory cell array includes a plurality of memory cells that are vertically stacked over the body substrate, and
wherein each of the memory cells includes:
a capacitor laterally spaced apart from the bit line;
an active layer laterally oriented between the bit line and the capacitor; and
a word line positioned in an upper portion of at least one of an upper surface and a lower surface of the active layer, and laterally extending in a direction intersecting the active layer.
